(19) United States
(12) Patent Application Publication
(10) Pub. No.: US 2013/0162275 A1
(43) Pub. Date: Jun. 27, 2013

(54) SEMICONDUCTOR DEVICE HAVING COMMAND MONITOR CIRCUIT

(71) Applicant: Elpida Memory, Inc., Tokyo (JP)

(72) Inventors: Kazuhiro KURIHARA, Tokyo (JP); Toru ISHIKAWA, Tokyo (JP)

(73) Assignee: Elpida Memory, Inc., Tokyo (JP)

(21) Appl. No.: 13/720,779

(22) Filed: Dec. 19, 2012

(30) Foreign Application Priority Data
Dec. 26, 2011 (JP) 2011-284332

(51) Int. Cl. G01R 31/27

(52) U.S. Cl. CPC G01R 31/275
USPC 324/750.3

(57) ABSTRACT

A semiconductor device includes a plurality of channels, a plurality of command monitor circuits provided corresponding to the plurality of channels, respectively, and a plurality of signal lines coupled in common to the plurality of command monitor circuits. Each of the plurality of command monitor circuits includes a selector configured to receive a plurality of input signals and selectively output a plurality of selected signals among the input signals, based on a first selection information, and an output circuit coupled between the selector and the plurality of signal lines, and configured to output the selected signals to the plurality of signal lines, respectively, based on a second selection information. One of the plurality of command monitor circuits is selected to output the selected signals to the plurality of signal lines while the remaining of the command monitor circuits is non selected, based on the second selection information.

### BACKGROUND OF THE INVENTION

1. Field of the Invention

The present invention relates to a semiconductor device, and particularly relates to a semiconductor device comprising semiconductor chips controlled by a control chip.

2. Description of Related Art

In general, when various tests are performed for the purpose of analyzing operation defects or the like in a semiconductor device such as DRAM (Dynamic Random Access Memory), it is necessary to monitor various signals that are used in internal circuits. In such tests, assuming a semiconductor devise as a system including a control chip as a controller and semiconductor chips such as DRAMs, various signals are to be transmitted from each of the semiconductor chips controlled by the control chip through a predetermined path to the control chip. For example, Patent Reference 1 discloses a configuration in which a test signal is transmitted from a semiconductor control chip (logic chip 11) through an access path to a control chip. Further, for example, Patent Reference 2 discloses a configuration in which each state of a plurality of nodes in a data retention circuit is selected by a test signal and the selected state is outputted as a monitor signal from a monitor terminal.
[Patent Reference 1] Japanese Patent Application Laid-open No. 2004-158098 (U.S. Pat. No. 6,925,018)
[Patent Reference 2] Japanese Patent Application Laid-open No. 2005-149548

The above system generally has a configuration in which one control chip and one or a plurality of semiconductor chips are provided and each of the semiconductor chips has an interface with the control chip without having a direct interface with outside. In such a system, access to the semiconductor chips is performed only through the control chip. Therefore, if a failure occurs in the system, it is very difficult to determine whether the failure is caused by the control chip or each of the semiconductor chips without disassembling the semiconductor device including the chips because respective operations of the chips cannot be confirmed.

### SUMMARY

As to an aspect of a present invention, a semiconductor device includes a plurality of channels, a plurality of command monitor circuits provided corresponding to the plurality of channels, respectively, and a plurality of signal lines coupled in common to the plurality of command monitor circuits. Each of the plurality of command monitor circuits includes a selector configured to receive a plurality of input signals and selectively output a plurality of selected signals among the input signals, based on a first selection information, and an output circuit coupled between the selector and the plurality of signal lines, and configured to output the selected signals to the plurality of signal lines, respectively, based on a second selection information. One of the plurality of command monitor circuits is selected to output the selected signals to the plurality of signal lines while the remaining of the command monitor circuits is non selected, based on the second selection information.

As to an another aspect of a present invention, a semiconductor chips includes a control chip, a plurality of semiconductor chips stacked over the control chip, which are configured to be controlled by the control chip, the plurality of semiconductor chips each including a plurality of memory channels and a plurality of command monitor circuits provided corresponding to the memory channels, respectively, the command monitor circuit being configured to output a plurality of monitor signals produced in the associated semiconductor chip when controlled by the control chip in a test mode, and a plurality of signal lines passing through the plurality of semiconductor chips so that the plurality of signal lines are coupled to the command monitor circuits in each of the semiconductor chips. One of the plurality of command monitor circuits in the plurality of semiconductor chips is selected to output the monitor signals to the plurality of signal lines, based on a selection information.

### BRIEF DESCRIPTION OF THE DRAWINGS

FIG. 1 is a diagram schematically showing an example of a cross-sectional structure of a semiconductor device 10 of an embodiment;

FIG. 2A is a conceptual diagram of each of semiconductor chips C0 to C3 of FIG. 1;

FIG. 2B is a block diagram showing a specific configuration example of an internal circuit 20 of FIG. 2A;

FIG. 3 is a diagram showing a configuration example of a command monitor circuit 24 included in each channel of FIG. 2A;

FIG. 4 is a diagram showing a circuit configuration example of an output circuit 33 included in the command monitor circuit 24 of FIG. 3;

FIG. 5 is a diagram showing a connection relation between respective command monitor circuits 24 of four channels 0 to 3;

FIGS. 6A and 6B are diagrams showing setting examples of a test register 31 of the command monitor circuit 24 of FIG. 3;

FIGS. 7A and 7B are diagrams showing two examples of monitoring operations when a pattern 100 is set in a sub-register<2:0> of the test register 31;

FIG. 7C is a diagram showing a modified example obtained by introducing a configuration to achieve the monitoring operations of FIGS. 7A and 7B in the configuration example of the monitor circuit 24 of FIG. 3;

FIG. 8 is a diagram showing an example of a monitoring operation when a pattern 001 is set in the sub-register<2:0> of the test register 31;

FIG. 9 is a diagram showing an example of a monitoring operation when a pattern 011 is set in the sub-register<2:0> of the test register 31;

FIG. 10 is a diagram showing a configuration example of a system comprising the memory device of an embodiment; and

FIG. 11 is a diagram showing a modification of the connection relation between the respective command monitor circuits 24 of FIG. 5.

### DETAILED DESCRIPTION OF THE PREFERRED EMBODIMENTS

Hereinafter, embodiments of the present invention will be described in detail with reference to accompanying drawings. In the following embodiments, a configuration comprising a plurality of DRAM chips and a control chip will be described as an example of a semiconductor device. However, the present invention is not limited to the following embodiments.

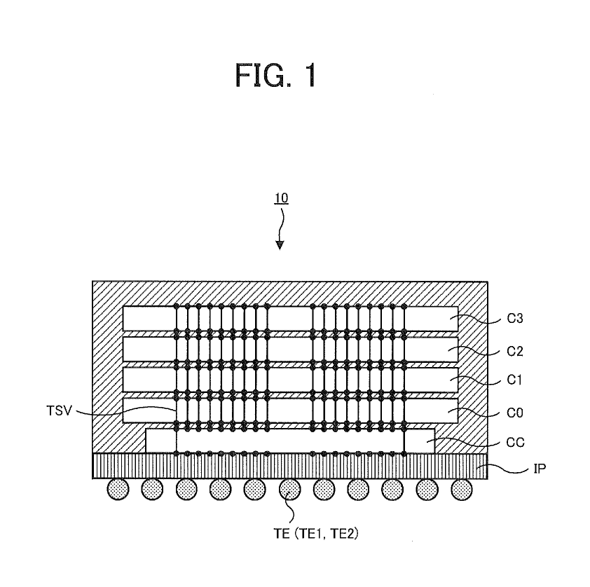

FIG. 1 schematically shows an example of a cross-sectional structure of a semiconductor device 10. The semiconductor device 10 of an embodiment has a structure in which five chips are stacked together. That is, one control chip CC and four semiconductor chips C0, C1, C2 and C3 are stacked from the bottom, and an interposer IP as a package substrate is disposed in a lowermost layer. The four semiconductor chips C0 to C3 are so-called Wide I/O DRAM chips, which have the same function, structure and circuit pattern as one another. The control chip CC is, for example, a SOC (System on Chip) that controls the semiconductor device 10, and includes logic circuits for controlling respective operations of the semiconductor chips C0 to C3. The entire semiconductor device 10 is sealed by resin in a package.

Further, as shown in FIG. 1, a plurality of TSVs (Through-Silicon Vias) that are through electrodes extending in a stacking direction are formed in the semiconductor device 10. A plurality of external terminals TE are formed on a bottom face of the interposer IP of the semiconductor device 10, and are electrically connected to corresponding TSVs, respectively. The respective TSVs are electrically connected to terminals of the control chip CC and terminals of the semiconductor chips C0 to C3 in the semiconductor device 10. Thus, it is possible to communicate between the external terminals TE and circuits on the package substrate in a state where the semiconductor device 10 is mounted on the package substrate. In addition, the external terminals TE of the semiconductor device 10 include a plurality of external terminals TE1 used for communication between the control chip CC and the outside in a normal operation, and a plurality of external terminals TE2 used to monitor internal signals of the semiconductor chips C0 to C3 in a test operation, while not used in the normal operation. In addition, signals such as commands, addresses, input/output data (DQ) and a data strobe signal DQS, which are used in the DRAM, are supplied from the control chip CC through the TSVs, and signals for testing are transmitted to the external terminals TE2 without passing through the logic circuits in the control chip CC.

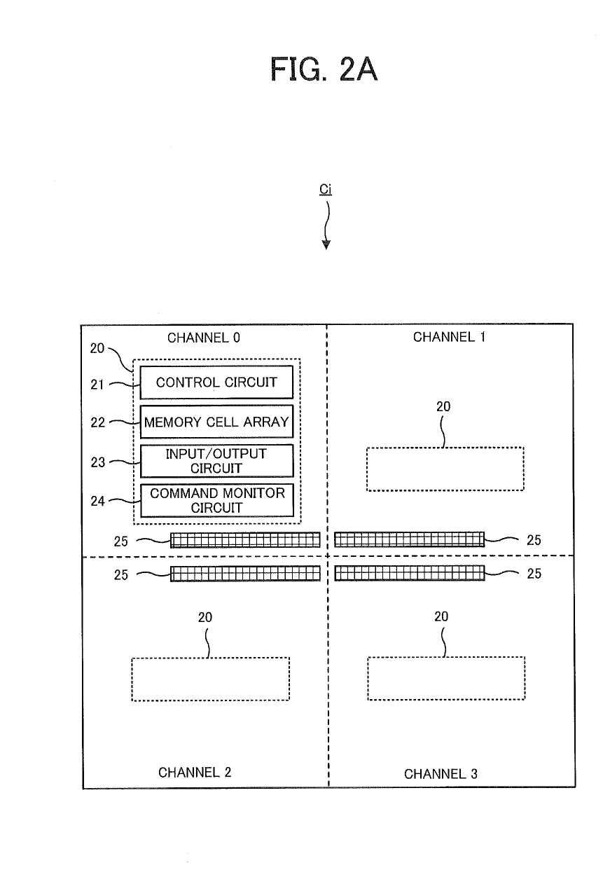

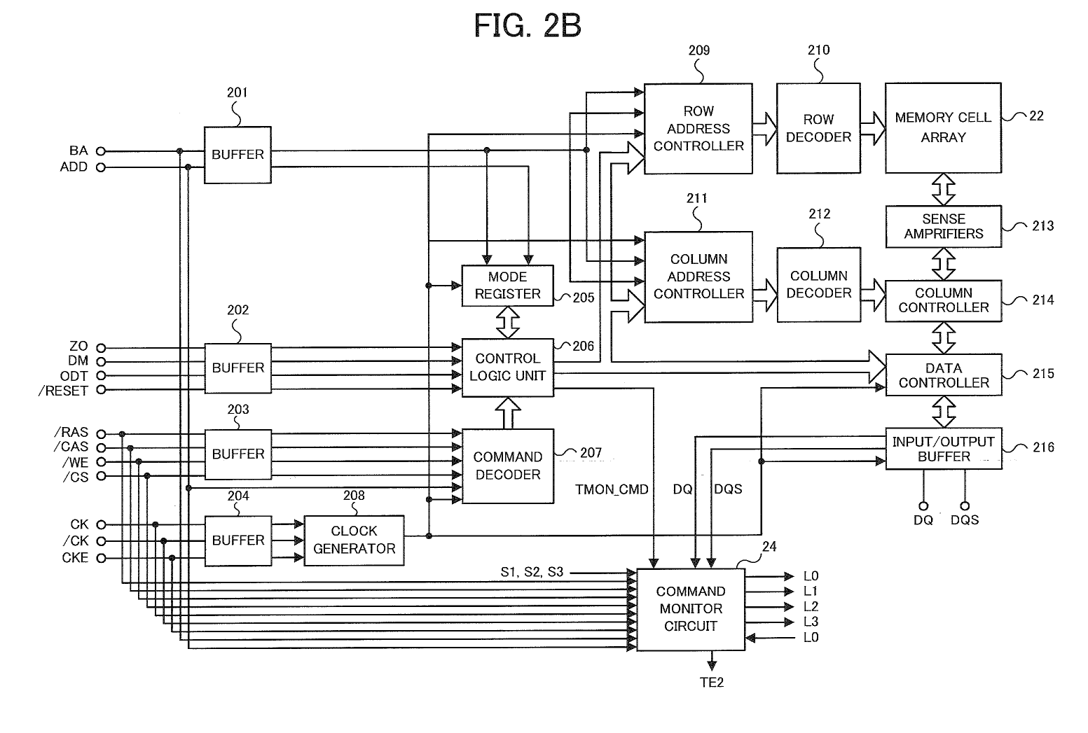

FIG. 2A is a conceptual diagram showing a semiconductor chip Ci (i=0 to 3) that is either one of the semiconductor chips C0 to C3 of FIG. 1. The semiconductor chip Ci shown in FIG. 2A includes channels 0 to 3 that are four unit regions each functions as the DRAM. Taking an example of the semiconductor device 10 of FIG. 1, DRAMs corresponding to 16 channels are included in the entire semiconductor device 10. As shown in FIG. 2A, each of the four channels 0 to 3 is provided with an internal circuit 20. The internal circuit 20 of each channel includes a control circuit 21 that controls operations in the channel, a memory cell array 22 that stores data, an input/output circuit 23 that controls data input/output from/to the outside, and a command monitor circuit 24 having a feature of the invention. Although elements of the internal circuit 20 are shown only in the channel 0, the same elements are also included in each of the channels 1, 2 and 3. Further, terminals 25 connected to the above-mentioned plurality of TSVs are arranged at an end of each channel, thereby making electrical connections from the internal circuit 20 to the terminals of the control chip CC and the external terminals TE through the terminals 25 and the TSVs.

Although the example of FIG. 1 shows that the semiconductor device 10 includes the four semiconductor chips C0 to C3, the number of semiconductor chips is not limited to four. Similarly, although the example of FIG. 2A shows that one semiconductor chip Ci includes four channels C0 to C3, the number of channels is not limited to four. Thus, a configuration may be employed in which the semiconductor device 10 includes M (M is an integer equal to or greater than 1) semiconductor chips and each semiconductor chip includes N (N is an integer equal to or greater than 1) channels. Further, the semiconductor device 10 of FIG. 1 may include chips other than the control chip CC and the semiconductor chips C0 to C3.

FIG. 2B is a block diagram showing a specific configuration example of the internal circuit 20, in which the channel 0 of the semiconductor chip Ci of FIG. 2A is exemplified. FIG. 2B shows four buffers 201 to 204, a mode register 205, a control logic unit 206, a command decoder 207, a clock generator 208, a row address controller 209, a row decoder 210, a column address controller 211, a column decoder 212, sense amplifiers 213, a column controller 214, a data controller 215, and an input/output buffer 216 of the input/output circuit 23 (FIG. 2A), in addition to the memory cell array 22 and the command monitor circuit 24 of FIG. 2A. Many of these elements are arranged inside the control circuit 21 (FIG. 2A) or around the memory cell array 22.

In FIG. 2B, the buffer 201 receives address signals (Add and BA), the buffer 202 receives control signals (ZO, DM, ODT and /RESET) related to operation control of the DRAM, the buffer 203 receives control signals (/RAS, /CAS, /WE and /CS) related to commands, and the buffer 204 receives clock related signals (CK, /CK and CKE), among signals supplied from the control chip CC. In addition, the signals received to the buffers 201, 203 and 204 are also received to the command monitor circuit 24.

The address signals of the buffer 201 include a row address received to the row address controller 209 and a column address received to the column address controller 211. Further, operation modes stored in the mode register 205 are set based on the above address signals. The control logic unit 206 controls operations of various parts of the internal circuit 20 based on the control signals received via the buffer 202. The command decoder 207 decodes the control signals received via the buffer 203, and sends them to the control logic unit 206. In addition, the command decoder 207 sends a test command TMON_CMD, which will be described later, to the command monitor circuit 24. The clock generator 20 generates internal clocks based on the signals received via the buffer 204, and sends them to various parts.

The memory cell array 22 includes a plurality of memory cells, and it is possible to access a memory cell selected by the row decoder 210 and the column decoder 212. Data of memory cells accessed in the memory cell array 22 are amplified by the sense amplifiers 213, and are transmitted to/from the input/output buffer 216 through the column controller 214 and the data controller 215. The input/output buffer 216 inputs and outputs the input/output data DQ from/to the outside in response to the data strobe signal DQS. In FIG. 2B, an operation of the command monitor circuit 24 will be described later.

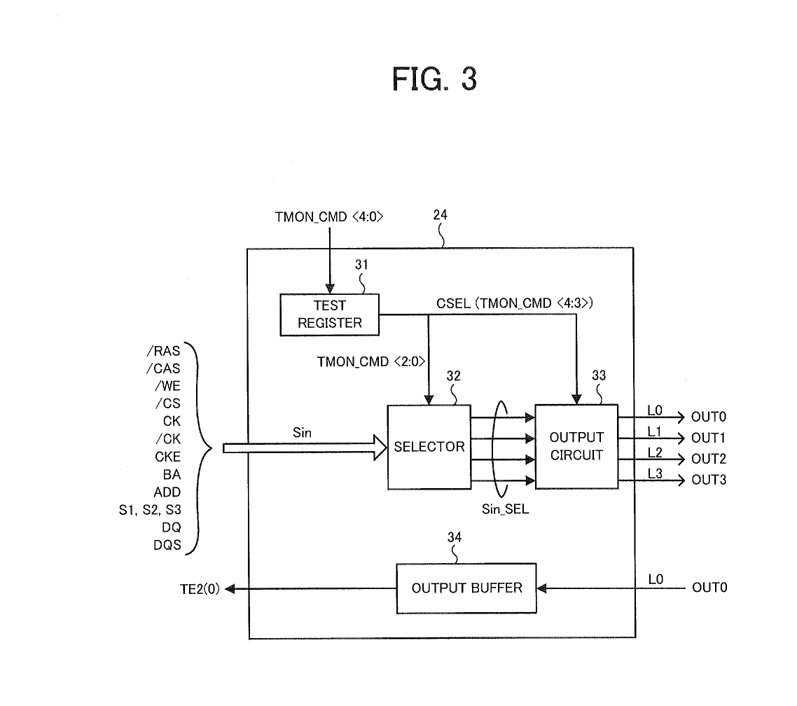

Next, FIG. 3 shows a configuration example of the command monitor circuit 24 included in each channel of FIG. 2A. Hereinafter, the command monitor circuit 24 of the channel 0 will be described in the example of FIG. 3. The command monitor circuit 24 shown in FIG. 3 includes a test register 31, a selector 32, an output circuit 33, and an output buffer 34. The test register 31 stores selection information having a predetermined number of bits, which includes information for selectively activating a channel to be monitored (first selection information) and information for selecting signals to be monitored (second selection information). The selection information is set in the test register 31 based on the test command TMON_CMD (FIG. 1) sent from the control logic unit 206. The test command TMON_CMOD is, for example, a command corresponding to test items performed for a specified semiconductor chip Ci under control of the command control chip CC. The example of FIG. 3 shows a case where the test register 31 receives a 5-bit test command TMON_CMD<4:0>.

The selector 32 receives a plurality of input signals Sin including the control signals (/RAS, /CAS, /WE and /CS) supplied via the buffer 203 (FIG. 2A), the clock related signals (CK, /CK and CKE) supplied via the buffer 204 (FIG. 2A), the address signals (Add and BA) supplied via the buffer 201 (FIG. 2A), internal signals S1, S2 and S3 generated in the internal circuit 20 (FIG. 1), the input/output data DQ and the data strobe signal DQS. The selector 32 selectively outputs four signals Sin_SEL among the plurality of input signals Sin in accordance with a 3-bit test command TMON_CMD<2:0> sent from the test register 31. Further, the output circuit 33 receives the four signals Sin_SEL selected by the selector 32, and sends them as four output signals OUT<0:3> in accordance with a channel selection signal CSEL composed of a 2-bit test command TMON_CMD<4:3> sent from the test register 31. These output signals OUT<0:3> are transmitted through four internal lines L0 to L3, respectively.

In a normal mode of the DRAM, an operation of the command monitor circuit 24 is controlled by the mode register 205 (FIG. 2B). On the other hands, a test mode of the DRAM is entered by issuing a command for the test mode. In the test mode for the configuration of FIG. 3, a test operation of the command monitor circuit 24 is controlled by the test register 31. Although many test registers for controlling test operations are actually provided in the DRAM, only the test register 31 used as a test monitor for the test command monitor circuit 24 will be described.

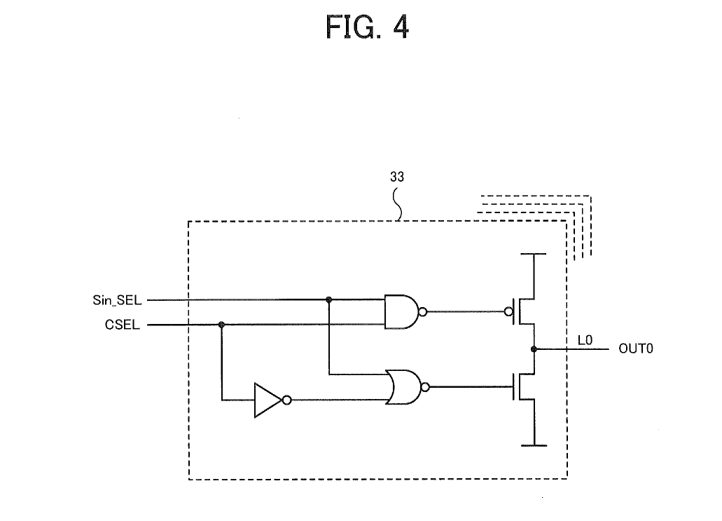

FIG. 4 shows a circuit configuration example of the output circuit 33 outputting the output signal OUT<0> of FIG. 3. Although the output circuit 33 includes four circuit portions from which the respective four output signals OUT<0:3> are outputted, only one circuit portion thereof from which the output signal OUT<0> is outputted will be described. In FIG. 4, a signal Sin_SEL is inputted to a NAND gate and a NOR gate, and the above channel selection signal CSEL is inputted to the NOR gate through an inverter. In this configuration, when the channel selection signal CSEL is at a high level, the output signal OUT<0> is outputted via a transistor circuit at the output stage, and the output signal OUT<0> is transmitted through the internal line L0. On the other hand, when the channel selection signal CSEL is at a low level, the output signal OUT<0> is not outputted from the transistor circuit. In addition, the configuration and operation are the same regarding three output circuits 33 outputting other three output signals OUT<1:3>. In this manner, whether or not each of the output signals OUT<0:3> is to be outputted is controlled in accordance with the channel selection signal CSEL.

Returning to FIG. 3, the output buffer 34 receives and buffers the output signal OUT<0> that is transmitted through the internal line L0 corresponding to the channel 0, and outputs it to an external terminal TE2(0) through one of the terminals 25 and the TSVs. Thereby, it is possible to monitor the output signal OUT<0> via one of the external terminals TE2. In this manner, only output nodes of the output buffers 34 in the command monitor circuit 24 are connected to the external terminals TE2 of the semiconductor device 10.

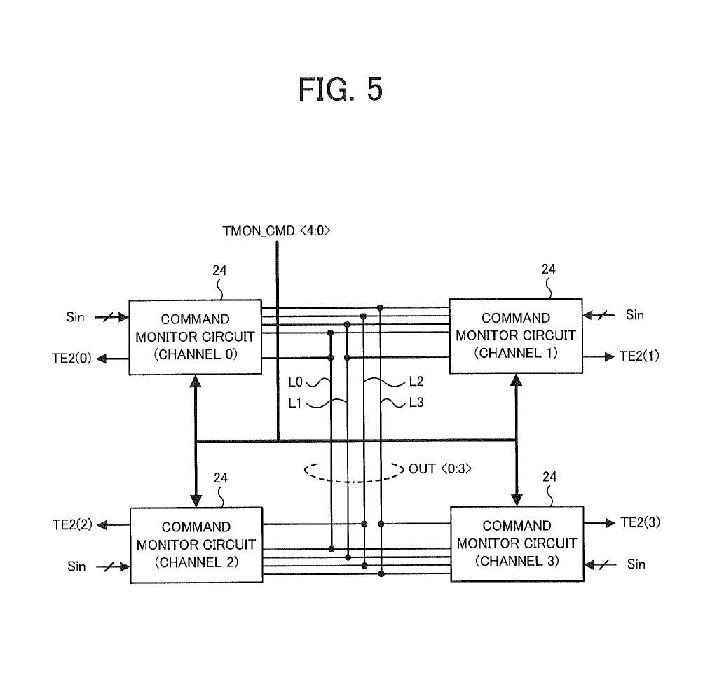

Next, a connection relation between the respective command monitor circuits 24 of the four channels 0 to 3 will be described with reference to FIG. 5. As shown in FIG. 5, the above-mentioned plurality of input signals Sin are supplied from the control chip CC to each of the command monitor circuits 24 of each channel. Further, each of the command monitor circuits 24 of each channel is connected to a corresponding external terminal TE2, as described in FIG. 3. That is, four external terminals TE2(0) to TE2(3) that are corresponded to the four channels 0 to 3 exist. On the other hand, the respective command monitor circuits 24 of the respective channels are interconnected with one another through the internal lines L0 to L3 formed on a single semiconductor chip Ci. Further, the 5-bit test command TMON_CMD<4:0> is supplied to each of the command monitor circuits 24 of each channel from the control logic unit 206 (FIG. 2B).

As shown in FIG. 5, each of the four command monitor circuits 24 is connected to the four internal lines L0 to L3 shared by the four channels 0 to 3, and the four output signals OUT<0:3> are transmitted through the four internal lines L0 to L3. Further, each of the command monitor circuits 24 is connected to one internal line Ln(n=0 to 3) among the four internal lines L0 to L3 of the output signals OUT<0:3>, which is different for each channel. In the example of FIG. 5, the command monitor circuit 24 of the channel 0 is connected to the internal line L0 of the output signal OUT<0>, the command monitor circuit 24 of the channel 1 is connected to the internal line L1 of the output signal OUT<1>, the command monitor circuit 24 of the channel 2 is connected to the internal line L2 of the output signal OUT<2>, and the command monitor circuit 24 of the channel 3 is connected to the internal line L3 of the output signal OUT<3>. For example, assuming that the channel 3 is selected as a channel to be monitored, the four output signals OUT<0:3> outputted from the command monitor circuit 24 of the channel 3 are separated into the four command monitor circuits 24 of the four channels 0 to 3 through the four internal lines L0 to L3, and thereafter the four output signals OUT<0:3> are transmitted to the four external terminals TE2(0) to TE2(3).

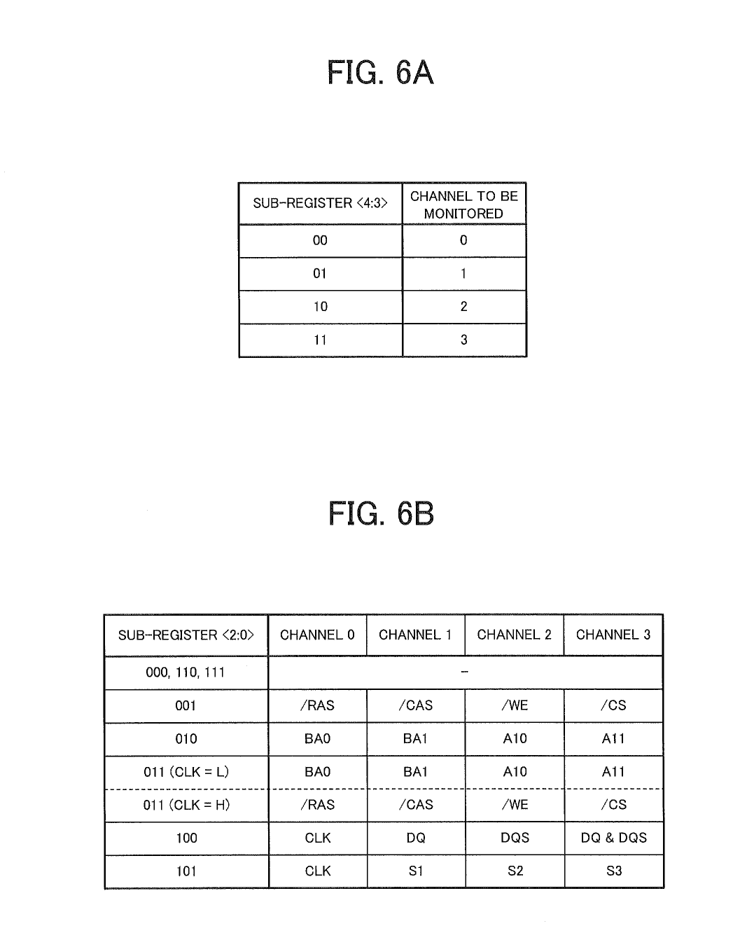

Next, setting examples of the test register 31 of the command monitor circuit 24 will be described with reference to FIGS. 6A and 6B. In the embodiments, the test register 31 that stores the 5-bit test command TMON_CMD<4:0> as the selection information is assumed to be composed of a sub-register<4:3> of the upper 2 bits (first selection information) for selecting a channel to be monitored and a sub-register<2:0> of the lower 3 bits (second selection information) for selecting signals to be monitored. FIG. 6A shows a setting example of the sub-register<4:3>. As shown in FIG. 6A, when patterns 00, 01, 10 and 11 are set in the sub-register<4:3>, respectively, channels 0, 1, 2 and 3 to be monitored are selected in this order.

Further, FIG. 6B shows a setting example of the sub-register<2:0>. As shown in FIG. 6B, four signals corresponding to the four channels 0 to 3 are selected from among the plurality of input signals Sin in accordance with the pattern of the sub-register<2:0>, which serve as the signals to be monitored in the test operation for the selected channel. Then, the four signals are outputted via the four external terminals TE2(0) to TE2(3), respectively. Here, the patterns 000, 110 and 111 in the sub-register<2:0> are not used, while other five patterns are used. For example, when the pattern 001 is set in the sub-register<2:0>, four control signals /RAS, /CAS, /WEB and /CS are selected as the signals to be monitored, and when the pattern 010 is set in the sub-register<2:0>, four address signals BA0, BA1, A10 and A11 are selected as the signals to be monitored.

The pattern 011 of the sub-register<2:0> is for selecting different signals depending on the level of the clock CLK in each channel. That is, the address signals BA0, BA1, A10 and A11 are selected during a time period when the clock CLK is at “L” level, and the control signals /RAS, /CAS, /WEB and /CS are selected during a time period when the clock CLK is at “H” level. Further, the pattern 100 of the sub-register<2:0> is for selecting the clock CLK, the input/output data DQ and the data strobe signal DQS, and an output of AND operation thereof (DQ&DQS), respectively. Furthermore, the pattern 101 of the sub-register<2:0> is for selecting the clock CLK and the internal signals S1, S2 and S3, respectively.

In FIG. 6B, the internal signals S1, S2 and S3 are, for example, signals outputted from the row address controller 209 or the column address controller 211 (signals related to commands ACT, READ and WRITE). Further, when the address signal A10 is at “H” level, a read/write operation with auto-precharge is designated, and when the address signal A10 is at “L” level, a read/write operation without auto-precharge is designated. Further, the address signal A11 is used to control an active operation, a read operation with auto-precharge, a write operation with auto-precharge, a read operation without auto-precharge, and a write operation without auto-precharge, respectively. By monitoring the address signals A10 and A11, it is possible to determine accuracy of the address signals A10 and A11 when a corresponding command is entered.

In addition, the clock CLK and the data strobe signal DQS are both supplied from the control chip CC to the semiconductor chip Ci. Further, the input/output data DQ is supplied based on data read out from the memory cell array 22 in the semiconductor chip Ci.

Further, various combinations of signals to be monitored can be selected without being limited to the setting example shown in FIG. 6B.

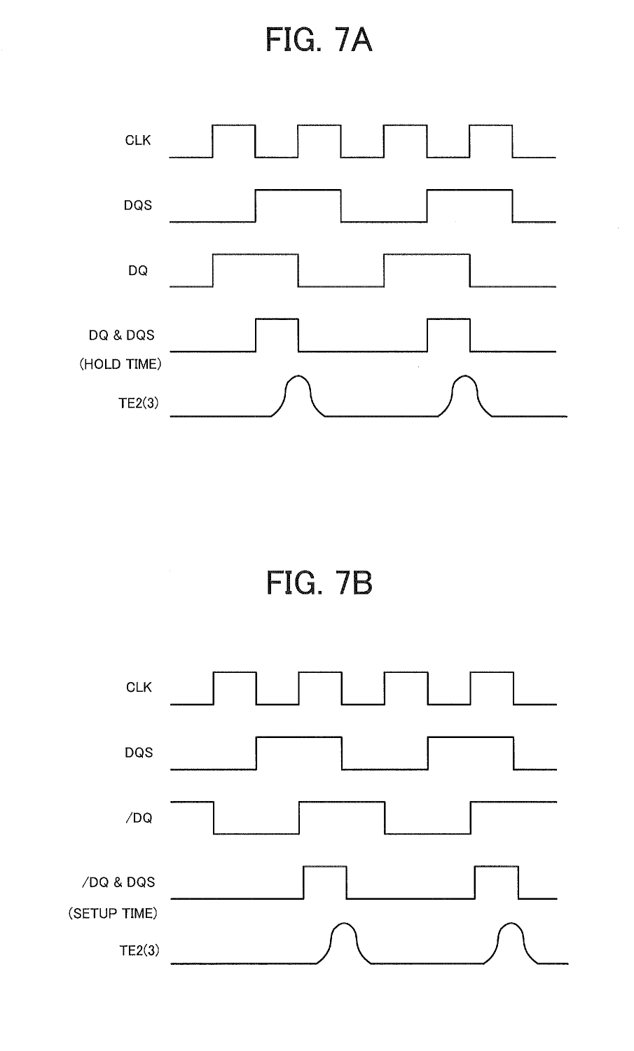

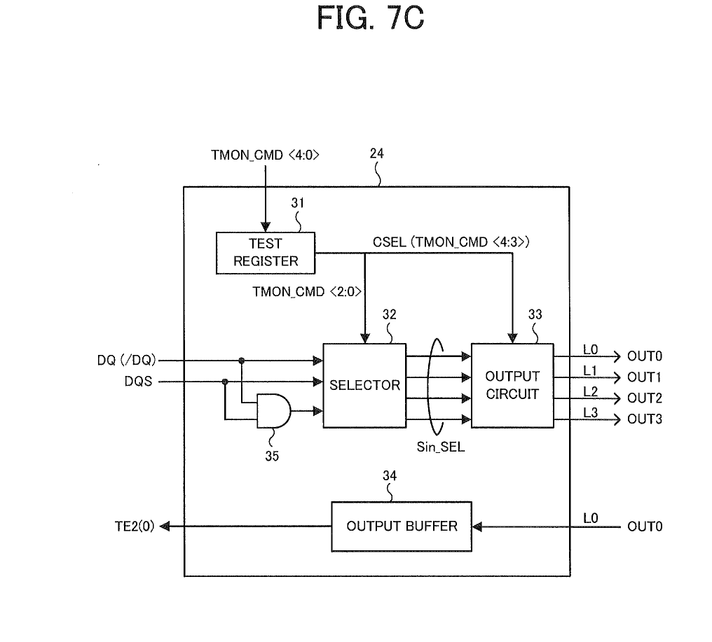

Next, a specific monitoring operation based on the setting example of the test register 31 of FIG. 6B will be described with reference to FIG. 7A to FIG. 9. FIGS. 7A and 7B show two examples of monitoring operations when the pattern 100 is set in the sub-register<2:0> of the test register 31. Each example of FIGS. 7A and 7B shows respective waveforms of the clock CLK having a predetermined period, the data strobe signal DQS, the input/output data DQ (/DQ), the output of AND operation DQ&DQS (/DQ&DQS) generated in the command monitor circuit 24, and the output of AND operation DQ&DQS (/DQ&DQS) transmitted to the external terminal TE2(3). In comparison between FIGS. 7A and 7B, since the respective input/output data DQ and /DQ are inverted to each other, the respective outputs of AND operation DQ&DQS and /DQ&DQS are also different from each other. In addition, the waveforms at the external terminal TE2(3) are blunted due to capacitances of transmission lines such as TSVs or loads of various circuits.

In FIG. 7A, a pulse of the output of AND operation DQ&DQS corresponding to a phase of the input/output data DQ enables to monitor “hold time” of the data strobe signal DQS relative to the input/output data DQ. On the other hand, in FIG. 7B, a pulse of the output of AND operation /DQ&DQS corresponding to a phase of the input/output data DQ enables to monitor “setup time” of the data strobe signal DQS relative to the input/output data /DQ. Thus, a desired data pattern of the input/output data DQ(/DQ) needs to be previously stored in the memory cell array 22 in accordance with whether the hold time or the setup time is to be monitored.

FIG. 7C shows a modified example obtained by introducing a configuration to achieve the monitoring operation of FIGS. 7A and 7B in the configuration example of the monitor circuit 24 shown in FIG. 3. In the monitor circuit 24 shown in FIG. 7C, the input/output data DQ or /DQ and the data strobe signal DQS among the input signals Sin shown in FIG. 3 are inputted, and an AND gate 35 is added to the configuration of FIG. 3. The input/output data /DQ is obtained by inverting the input/output data DQ received to the input/output buffer 216 of FIG. 2B. Thereby, although the state shown in FIG. 6B includes only one output of AND operation (DQ&DQS), it is possible to achieve both two monitoring operations of FIGS. 7A and 7B by obtaining the inverted input/output data /DQ.

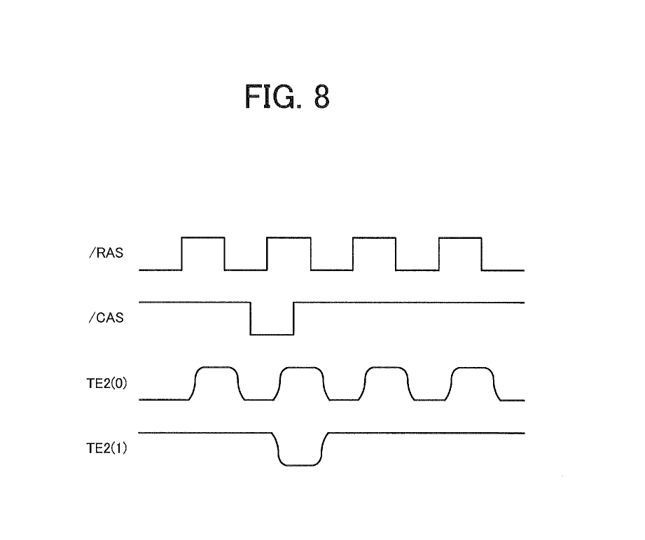

FIG. 8 shows an example of a monitoring operation when the pattern 001 is set in the sub-register<2:0> of the test register 31. The example of FIG. 8 shows waveforms of the control signals /RAS and /CAS, a waveform of the control signal /RAS transmitted to the external terminal TE2(0), and a waveform of the control signal /CAS transmitted to the external terminal TE2(1), respectively. In FIG. 8, the control signals /WE and /CS are omitted. It is found that each waveform of the control signals /RAS and /CAS at the external terminals TE2(0) and TE2(1) has a transmission delay and is blunted, since the waveforms pass through a plurality of circuits and transmission lines.

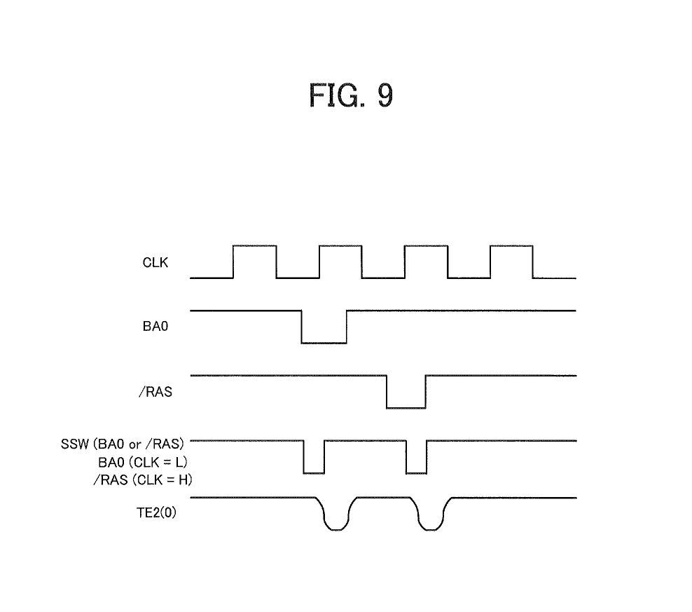

FIG. 9 shows an example of a monitoring operation when the pattern 011 is set in the sub-register<2:0> of the test register 31. The example of FIG. 9 shows the clock CLK having the predetermined period, waveforms of the address signal BA0 and the control signal /RAS, a waveform of a signal SSW that is switched between the address signal BA0 and the control signal /RAS in response to the level of the clock CLK, and a waveform of the signal SSW transmitted to the external terminal TE2(0), respectively. In this example, the signal SSW is controlled in accordance with a logic such that the address signal BA0 is outputted when the clock CLK is at “L” level and the control signal /RAS is outputted when the clock CLK is at “H” level. In the monitoring operation of FIG. 9, it is possible to monitor eight signals in total at the same time, including four signals outputted when the clock CLK is at “L” level and four signals outputted when the clock CLK is at “H” level.

As described above, by employing the configuration and control of the embodiments, various signals in the semiconductor chips C0 to C3 can be freely monitored from outside. That is, in a certain channel in the semiconductor chip Ci that is selected in accordance with the selection information of the test register 31, it is possible to monitor the control signals themselves by using the signals Sin_SEL having the same waveforms as the control signals supplied from the control chip CC. Or, it is possible to monitor the various signals that depend on operating conditions by performing a logical operation for two or more control signals so as to output its result as the signal Sin_SEL, or by outputting each of two or more control signals as the signal Sin_SEL selectively in response to the phase of the clock CLK, thereby obtaining operation information useful for analyzing defects of the semiconductor chip Ci.

Further, by employing the configuration and control of the embodiments, since the four command monitor circuits 24 of the channels 0 to 3 shown in FIG. 3, for example, can share the four external terminals TE2 for externally outputting the respective four output signals OUT<0:3>, it is possible to simplify the wiring structure of the semiconductor device 10. That is, by sequentially switching the four command monitor circuits 24, the 16 output signals OUT<0:3> can be sequentially outputted to outside. Thus, the internal lines L0 to L3 of the semiconductor chips C0 to C3 are effectively utilized, and it is possible to suppress the number of TSVs from the semiconductor chips C0 to C3 to the external terminals TE2. Further, since a selector for selecting a large number of signals is not required in the control chip CC, it is possible to reduce a circuit scale.

The above-described embodiments can solve a problem that occurs in a combination of the Patent References 1 and 2 disclosing the related configuration. That is, when terminals for monitoring are provided corresponding to each unit region of one or more semiconductor chips, the circuit scale inevitably increases. In this case, although a configuration provided with a selector for selecting signals to be monitored in the control chip can be employed, in which signals transmitted from each unit region of the semiconductor chip are selected by the selector, it is inevitable that the number of internal lines between the semiconductor chips and the control chip increases in addition to providing the selector separately. In this manner, according to the related configuration, it is difficult to achieve a configuration capable of freely extracting signals to be monitored in the semiconductor device comprising the control chip and the semiconductor chips without complicating the configuration. In contrast, according to the above-described embodiments, it is possible to easily extract the signals to be monitored without complicating the configuration.

As described above, the embodiments of the invention have been described. However the invention is not limited to the above embodiments and can be variously modified without departing the essentials of the invention. For example, although the semiconductor device 10 comprising one control chip CC and the four semiconductor chips C0 to C3 is shown in FIG. 1, the invention can be also applied to a semiconductor device 10 comprising one control chip CC and one semiconductor chip C0. In this case, the connection relation shown in FIG. 5 can be employed in the semiconductor chip C0, and thereby it is possible to obtain an effect of monitoring various signals of a plurality of channels with a simple configuration.

Further, although a plurality of semiconductor chips such as DRAM having a memory function are used in the embodiments, the invention is not limited thereto and can be widely applied to a semiconductor device comprising a plurality of semiconductor chips having various functions other than the memory function. Furthermore, circuits included in the semiconductor device of the invention are not limited to the circuit configurations disclosed in the embodiments, and various circuit configurations can be employed.

Further, although the semiconductor device 10 in which the four semiconductor chips (C0 to C3) are stacked is exemplified in the above embodiments, the invention can be preferably applied to a semiconductor device in which two or more semiconductor chips are stacked, and the configuration disclosed in the embodiments can be employed without being limited to the four semiconductor chips. Thereby, it is possible to employ a structure of such a semiconductor device in which an uppermost semiconductor chip does not include through electrodes and terminals and has a thickness larger than those of other semiconductor chips.

The invention can be applied to various semiconductor devices. For example, semiconductor devices such as CPU (Central Processing Unit), MCU (Micro Control Unit), DSP (Digital Signal Processor), ASIC (Application Specific Integrated Circuit) and ASSP (Application Specific Standard Product) can be employed. Further, the invention can be applied to various device structures such as SOC (System on Chip), MCP (Multi Chip Package) and POP (Package on Package).

Field-effect transistors (FETs) can be used as transistors included in logic circuits of the semiconductor device of the invention, and various FETs such as not only MOS (Metal Oxide Semiconductor) transistors but also MIS (Metal-Insulator Semiconductor) transistors may be used. Further, the semiconductor device may partially include bipolar transistors. Furthermore, an NMOS transistor (N channel type transistors) is a typical example of a first conductive type transistor, and a PMOS transistor (P-channel type transistor) is a typical example of a second conductive type transistor.

The invention can be applied to devices based on various combinations or selections of the disclosure of the embodiments. That is, the invention covers various modifications which those skilled in the art can carry out in accordance with all disclosures including claims and technical ideas.

### [System]

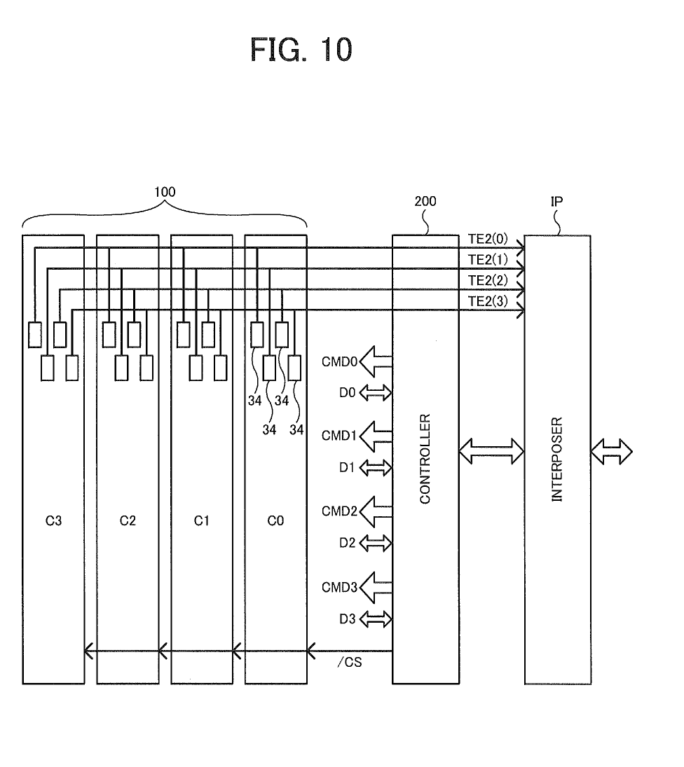

In the following, the semiconductor device 10 of the embodiments will be additionally described from the perspective of a system. FIG. 10 shows a configuration example of a system comprising a memory device 100 including the semiconductor chips C0 to C3, a controller 200 as the control chip CC and an interposer IP as a package substrate, in the semiconductor device 10 shown in FIG. 1. The controller 200 sends commands CMD0 to CMD3 to the memory device 100, and the controller 200 and the memory device 100 mutually send and receive data D0 to D3. Further, the controller 200 selects one semiconductor chip Ci from among the four semiconductor chips C0 to C3 by outputting the control signal /CS, and selects one of the four channels 0 to 3 of the selected chip. FIG. 10 shows a connection relation between 16 output buffers 34 (FIG. 3) included in the four channels 0 to 3 of the respective four semiconductor chips C0 to C3 and the four external terminals TE2(0) to TE2(3) of the interposer IP. Thus, the four output buffers 34 in the semiconductor chip Ci corresponding to the selected channel is capable of outputting the respective signals to the four external terminals TE2(0) to TE2(3) without interfering with the output buffers 34 of other semiconductor chips in which output nodes of the output buffers 34 are in a floating state, respectively.

As shown in FIG. 10, paths for transmitting signals to be monitored in the channels 0 to 3 are directly connected to the four external terminals TE2(0) to TE2(3) of the interposer IP from the four terminals of the memory device 100 through the four TSVs without passing through the logic circuits in the controller 200. The feature is that the signals to be monitored in the channels 0 to 3 are not introduced into the controller 200 and are sent from the interposer IP to an external interface. Thereby, it is possible to directly monitor the signals by using an external apparatus.

Although the interposer IP as the package substrate is shown in FIGS. 1 and 10, the controller 200 (control chip CC) may be configured to be directly connected to the external interface without providing the interposer IP. In this case, also the signals to be monitored are transmitted to the external interface without passing through the logic circuits in the controller 200.

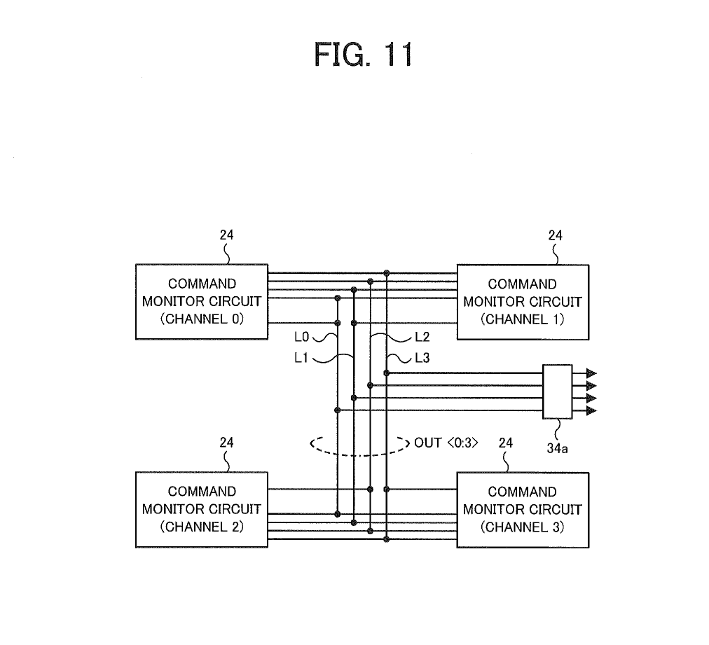

In the following, a modification of the connection relation between the command monitor circuits 24 shown in FIG. 5 will be additionally described. An output buffer 34a to which the four internal lines L0 to L3 of FIG. 5 are connected is added in the modification shown in FIG. 11. The output buffer 34a integrally includes the four output buffers 34 (FIG. 3) of the channels 0 to 3, which are omitted in FIG. 11. In case of FIG. 5, the output signals OUT<0:3> are outputted to outside through the respective command monitor circuits 24, and on the other hand, in case of the modification of FIG. 11, the output signals OUT<0:3> can be outputted to outside from one output buffer 34a without passing through the respective command monitor circuits 24. Further, although the four internal lines L0 to L3 of FIG. 11 are connected to the output buffer 34a, a configuration may be employed in which four output lines for the four channels are separated from one another and in total 16 signals to be monitored may be directly transmitted through 16 output lines to the interposer IP. In this case, although 16 external terminals are required to perform a test operation, there is an advantage that the test operation can be performed for the four channels 0 to 3 at the same time. In case where the output buffer 34a is used in place of the output buffers 34, in FIG. 10, the output buffers 34 in each of the semiconductor chips C0 to C3 is replaced with the output buffer 34a, which is connected to the external terminals TE2(0) to TE2(3) via test signal lines.

1. A semiconductor device, comprising:
a plurality of channels;
a plurality of command monitor circuits provided corresponding to the plurality of channels, respectively; and
a plurality of signal lines coupled in common to the plurality of command monitor circuits;
each of the plurality of command monitor circuits comprising:
a selector configured to receive a plurality of input signals and selectively output a plurality of selected signals among the input signals, based on a first selection information; and
an output circuit coupled between the selector and the plurality of signal lines, and configured to output the selected signals to the plurality of signal lines, respectively, based on a second selection information,
wherein one of the plurality of command monitor circuits is selected to output the selected signals to the plurality of signal lines while the remaining of the command monitor circuits is non selected, based on the second selection information.

2. The semiconductor device as claimed in claim 1, wherein each of the plurality of command monitor circuits comprises:
an output buffer configured to receive a corresponding one of the selected signals via a corresponding one of the signal lines.

3. The semiconductor device as claimed in claim 1, the semiconductor device further comprising:
an output buffer configured to receive the selected signals via the signal lines.

4. The semiconductor device as claimed in claim 1, wherein the command monitor circuit further comprises a test register storing the first and second selection information.

5. The semiconductor device as claimed in claim 1, wherein the first selection information indicates an information for selecting the plurality of selected signals to be monitored and the second selection information indicates an information for selecting one of the channels to be monitored.

6. The semiconductor device as claimed in claim 1, wherein the command monitor circuit receives a signal input to a command decoder.

7. The semiconductor device as claimed in claim 6, wherein the signal includes a row address strobe signal.

8. The semiconductor device as claimed in claim 6, wherein the signal includes a column address strobe signal.

9. The semiconductor device as claimed in claim 6, wherein the signal includes a write enable signal.

10. The semiconductor device as claimed in claim 6, wherein the signal includes a chip selection signal.

11. The semiconductor device as claimed in claim 5, wherein the command monitor circuit receives a bank address.

12. The semiconductor device as claimed in claim 5, wherein the signal includes a clock signal.

13. The semiconductor device as claimed in claim 5, wherein the signal includes a data signal.

14. The semiconductor device as claimed in claim 13, wherein the signal includes a data strobe signal.

15. The semiconductor device as claimed in claim 14, the command monitor circuit further comprising:
a logic circuit receiving the data signal and the data strobe signal,
wherein the selector receives an output of the logic circuit.

16. A semiconductor chips comprising:
a control chip;
a plurality of semiconductor chips stacked over the control chip, which are configured to be controlled by the control chip, the plurality of semiconductor chips each including a plurality of memory channels and a plurality of command monitor circuits provided corresponding to the memory channels, respectively, the command monitor circuit being configured to output a plurality of monitor signals produced in the associated semiconductor chip when controlled by the control chip in a test mode;
a plurality of signal lines passing through the plurality of semiconductor chips so that the plurality of signal lines are coupled to the command monitor circuits in each of the semiconductor chips;
wherein one of the plurality of command monitor circuits in the plurality of semiconductor chips is selected to output the monitor signals to the plurality of signal lines, based on a selection information.

17. The semiconductor device according to claim 16, wherein the selection information includes a channel selection information and a chip selection information.

18. The semiconductor device according to claim 16, the semiconductor device further comprising:
an interposer provided such that the control chip is intervened between the semiconductor chips and the interposer, the interposer including a plurality of external terminals so that the signal lines pass through the control chip and are connected to the external terminals.

19. The semiconductor device according to claim 16, wherein the command monitor circuit comprises:
a selector configured to select and output selection signals among a plurality of input signals based on a first portion of the selection information;
an output circuit configured to output the selection signals, respectively, based on a second portion of the selection formation.

20. The semiconductor device according to claim 16, the command monitor circuit further comprising
a test register storing the selection information.
